(19) United States
(12) Patent Application Publication
(10) Pub. No.: US 2005/0204222 A1
(43) Pub. Date: Sep. 15, 2005

(54) Apparatus and method for eliminating the TMS connection in a JTAG procedure

(76) Inventor: Gary L. Swoboda, Sugar Land, TX (US)

Correspondence Address: TEXAS INSTRUMENTS INCORPORATED, P O BOX 655474, M/S 3999, DALLAS, TX, 75265, US

(21) Appl. No.: 11/080,701

(22) Filed: Mar. 15, 2005

Related U.S. Application Data
(60) Provisional application No. 60/553,081, filed on Mar. 15, 2004.

(51) Int. Cl. G01R 31/28

(52) U.S. Cl. 714/724

(57) ABSTRACT

In a JTAG procedure, the electrical coupling normally dedicated to the TMS information is eliminated. Instead, the TDI line signals are reformatted into control packets and data packets. The control packets include one field that provides the TMS information. The control packets result in either the SHIFT DR state or the SHIFT IR state. The remaining field(s) in a control packet indicates the number of data signals to be transmitted in the data packet that is transferred in the shift state. The control packet/data packet format can support directly addressing or indirect addressing mode.

This application claims priority under 35 USC §119(e) (1) of Provisional Application No. 60/553,081 (TI-38117PS) filed Mar. 15, 2004.

### BACKGROUND OF THE INVENTION

1. Field of the Invention

This invention relates generally to data processing systems and, more particularly, to the testing of integrated circuits using the JTAG procedures.

2. Background of the Invention

As the number of components and the complexity of integrated circuits have increased, the importance of testing these integrated circuits has increased. The importance of testing has become so great that many components in an integrated circuit are now dedicated to the testing (and program debug) involving these circuits. Concurrently, integrated circuits have continually been reduced in size. One of the most important consequences of this size reduction along with the increased complexity and functionality of the integrated circuit has been the problem of providing the necessary electrical connections between the integrated circuit and external components. The testing and program debug associated with the testing of the integrated circuit requires additional terminals. For example, the common Joint Test Action Group (JTAG) boundary scan procedure requires up to five terminals to accomplish a specified test procedure.

Referring to FIG. 1, the signal paths needed to implement the JTAG procedures are illustrated. An emulation unit 5 exchanges signals with an integrated circuit 10 and specifically with interface logic 11. The interface logic 11 exchanges signals with the processor core 15, the processing core 15 being the unit under test. The signals that are exchanged between the emulation unit 5 and the interface logic 11 include the TDI signals, the TCK signals, the TMS signals, the TRST signals, and the TDO signals.

Specifically, the TDI (test data in) signals are signals that are applied to interface logic 11 from the emulation unit 5 that are entered in the JTAG registers. The TDO (test data out) signals are serial output signals from JTAG registers to the emulation unit 5. The TCK (test clock) signals are signals that control th3e timing of the interface independently from any system clock. The TMS (test mode select) signals are the signals that control the transitions of the states of the interface logic 11. The TRST signals are the signals that initialize and disable the interface logic.

In the implementation of the JTAG procedures, TDI signals are serially scanned (by the TDI line) into the instruction registers and into the data registers in interface logic unit. The data signals are scanned into the boundary scan registers in the processing core and transferred to the processing core itself. In this manner, an initial state of the processing core can be established. Signals shifted into the instruction register (over the TDI line) control the operation of the processing core. Data resulting from operation of the processing core resulting from the instructions in the instruction register is then transferred to the boundary scan chain and transferred to the emulation unit. The TDO signals are then serially scanned out allowing the test apparatus to identify a subsequent (i.e., as compared to the initial) state. In some modes of operation, TDI signals can be scanned in while TDO signals are being scanned out.

Referring to FIG. 2, the JTAG state diagram for the interface logic 11 is shown. This state diagram is familiar to those skilled in the art and only those features necessary in understanding the present invention will be discussed. Every state has two exit paths. These exit paths are determined by the logic value of the signal on the TMS line. Five of the states are parking states, i.e. one logic signal (TMS=0) causes the state to remain unchanged. In FIG. 2, the parking states are RUN TEST IDLE state 21, SHIFT DR state 22, PAUSE DR state 23, SHIFT IR state 24, and PAUSE DR state 25. The IR designation refers to activity involving the instruction register wile the DR designation refers to activity involving the data register in the interface logic unit. The transfer of data from the interface logic 11 and the DR state refers to transfer of data to the interface logic 11. As will be clear, in the SHIFT DR state 22 and the SHIFT IR 24 states, while the state does not change, data is being transferred over the associated data in lime. Similarly with the RUN TEST IDLE state 21, the PAUSE DR state 23 and the PAUSE IR state 25, the state of the interface logic does not change and data is not transferred across the terminals.

Therefore, five terminals are used to provide an interface between the core processor under test and the emulation unit. The operation of the JTAG procedures includes many additional details that have not bee described here. The foregoing discussion provides only enough description to understand the present invention.

A need has therefore been felt for apparatus and an associated method having the feature of being able to reduce the number of terminals that provide for the interaction of external components with an integrated circuit. It would be a further feature of the apparatus and associated method to reduce the number of terminals needed in the JTAG test procedures. It would be yet a more particular object of the apparatus and associated method invention to reduce the number of terminals needed for a JTAG procedure by eliminating the TMS line. It would be still a more particular feature of the apparatus and associated method to combine the TMS state control information with the TDI information to control the operation of the exchange of signal groups between the emulation unit and the core processor.

### SUMMARY OF THE INVENTION

The foregoing and other features are accomplished, according the present invention, by providing apparatus associated with the emulation unit side of the terminal for combining the TMS signals and the TDI signals into common serial signal stream. A series of control packets that include the TMS signals plus control information are transmitted to the interface logic unit. The control information includes the length of signal packet to be transmitted after the control packets are concluded. The interface logic unit, based on the control signals of the control packets is then prepared for the transmission of number of logic states that has been communicated by the preceding control packets. In this manner, the TMS signal, that is repetitive (i.e., typically a logic “0”) in the transfer of signal groups is not transferred.

Other features and advantages of present invention will be more clearly understood upon reading of the following description and the accompanying drawings and the claims.

### BRIEF DESCRIPTION OF THE DRAWINGS

FIG. 1 is a block diagram of a configuration for testing an integrated circuit according to the prior art.

FIG. 2 is a block diagram of a configuration for testing integrated circuits according to the present invention.

FIG. 3 is a block diagram of a configuration for testing integrated circuits with JTAG procedures while eliminating the electrical coupling dedicated to the TMS information according to the prior art.

### DESCRIPTION OF THE PREFERRED EMBODIMENT

1. Detailed Description of the Figures

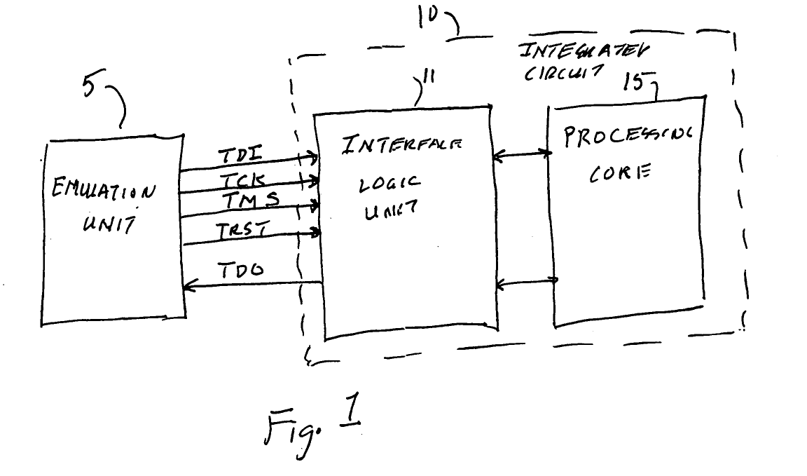

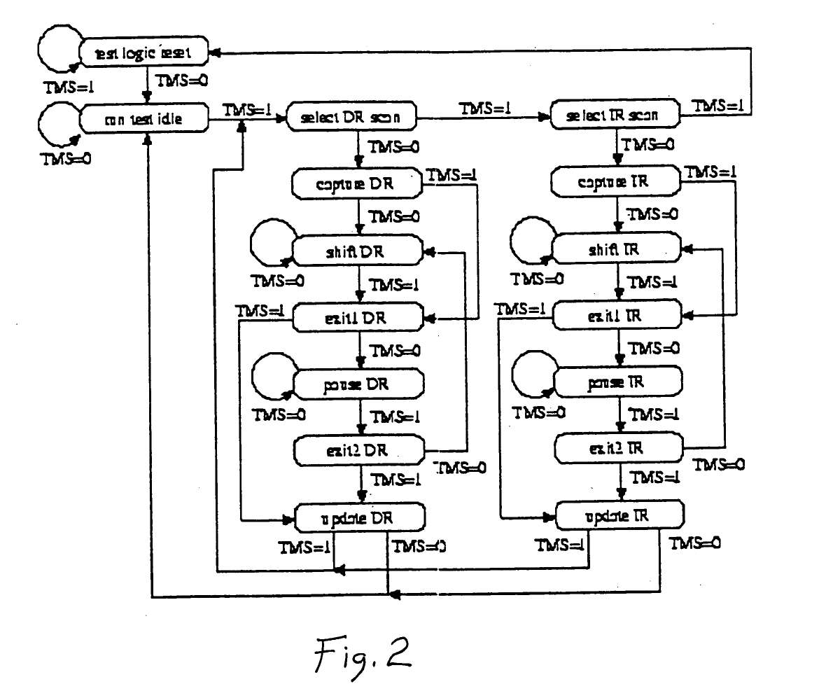

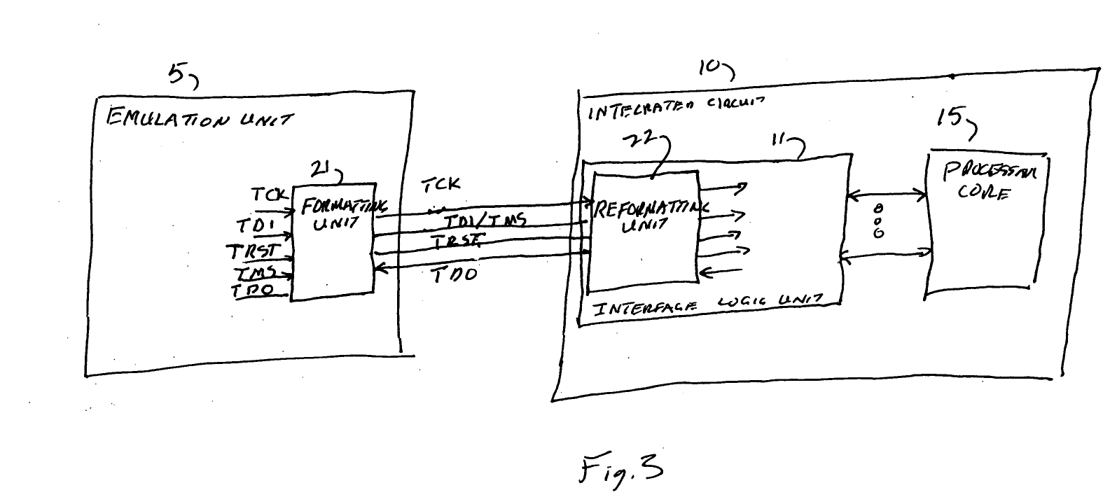

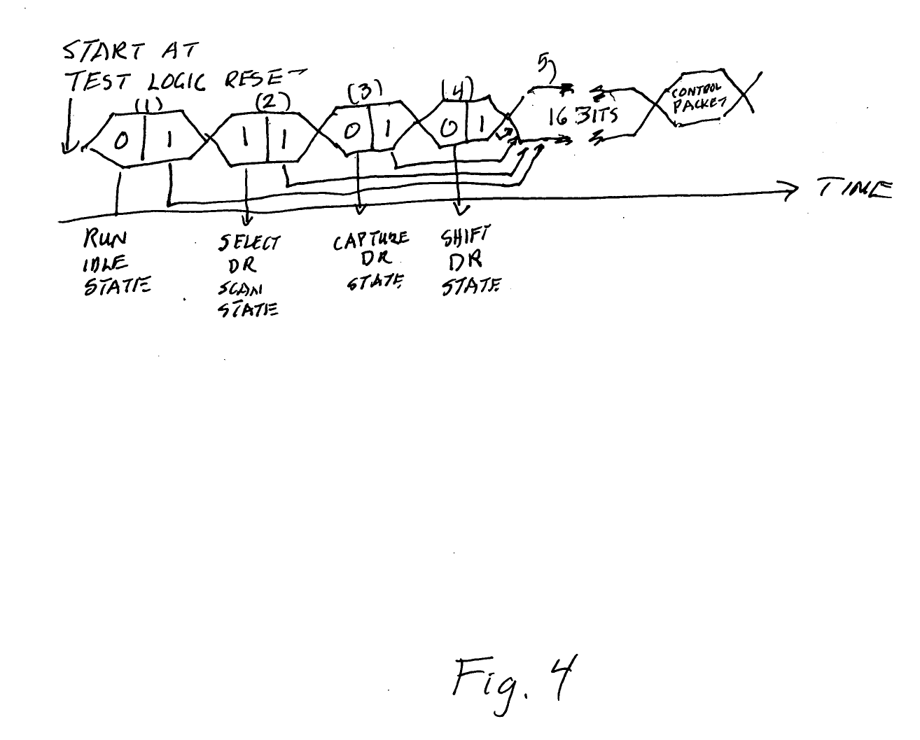

FIG. 1 and FIG. 2 have been described with respect to the prior art.

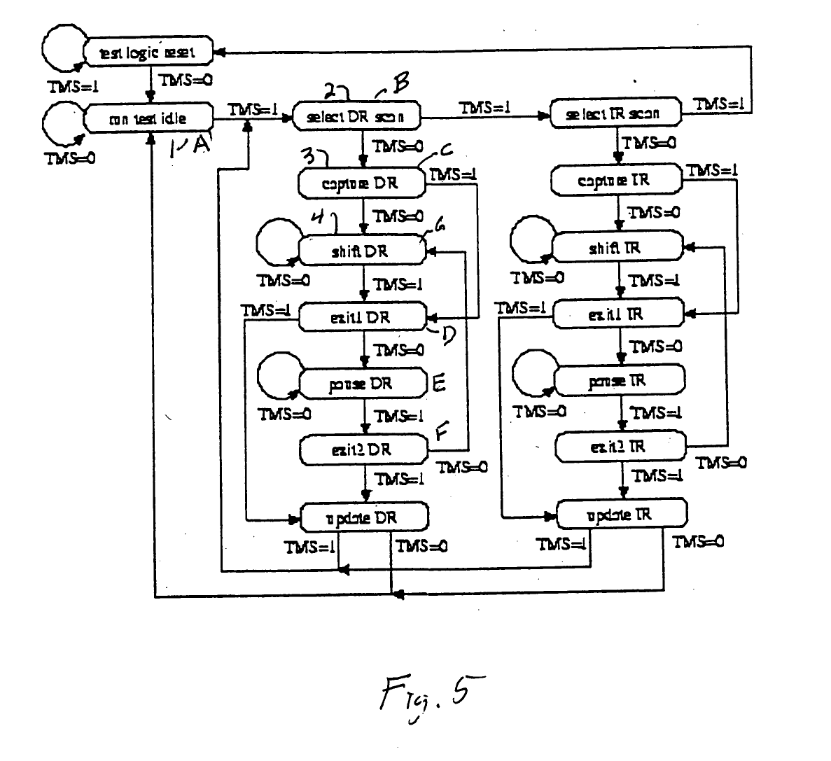

Referring to FIG. 3, a block of apparatus for eliminating the TMS line in a JTAG procedure is shown according the present invention. The present invention can be understood as providing a formatting unit 21 and a reformatting unit 22. The formatting unit 21 takes the signals on the five JTAG lines and transmits them in a modified form over four lines, the TMS line being eliminated and TMS information being added to the TDI line. The TDI signal stream from the formatting unit 21 has a series of packets. As an example, the series of packets has 2 bits. The first bit describes a state transition, while the second bit is part of a number or the address of a register that determines the number of bits in the data packet that follows the information packets.

Referring to FIG. 4 and FIG. 5, an example of the formatted signal packets is given. The packet includes TMS=0 in the first packet position changing the TEST LOGIC RESET state to the RUN TEST IDLE state. The subsequent control bits in packets 2, 3, and 4 changes the RUN TEST IDLE state to the SELECTY DR SCAN state (2) to the CAPTURE DR state (3) to the SHIFT DR state (4). Once the SHIFT DR state is reached, the next state is a group of data signals, the number group being determined by the second bit of the control packets or 16 (each of the group size control bits being one. Because four bits may not be sufficient to establish a size of the subsequent data group, the group number control bits can be used as an address for a register having storing a larger number. Or, the formatting unit can provide for a path determined by the TMS bits that follows the path shown in FIG. 5 as A, B, C, D, E, F, and G. With this path, the number of bits to specify a data group size or a register is 7.

At the end of the transmission of the data group, when the next TMS position in the next control packet is =0, then a data group of the same size can be transmitted over the TDI line. Or, and when a data group of a different size is to be transmitted, then the formatting unit 21 can automatically reset the state of the JTAG apparatus and start again, or the formatting unit 21 can provide a path in the JTAG state diagram (by use of TMS control signals) that reaches the SHIFT DR state again.

The reformatting unit 22 reconstructs the JTAG signals to the extent necessary to direct the TDI data signals to the proper address. The reformatting unit 22 must also transfer the TDO signals in a manner consistent with the operation of the formatting unit so that the formatting unit, upon receipt of the TDO data signals directs these data signals to the correct location in the emulation unit.

2. Operation of the Preferred Embodiment

The present invention relies on the fact that bulk of signals exchanged between the emulation unit and interface logic unit are the transfer of data to and from the data and instruction registers. The TMS signal that accompanies the transfer of groups is always the same. i.e., for the period of time of the signal group transfer. Because of the redundancy of the TMS signals during the data transfer, the combining of the TMS signals and the data signals on a single line results in the elimination of a signal stream between the emulation unit and the core processor with a relatively small increase in the time to transfer the information over a signal line.

In the foregoing discussion, the core processor has been described as the integrated circuit under test. The core processors are the target devices for the bulk of the test procedures. It will be clear that the JTAG boundary scan techniques can be applied to a wide variety of circuits.

While the invention has been described with respect to the embodiments set forth above, the invention is not necessarily limited to these embodiments. Accordingly, other embodiments, variations, and improvements not described herein are not necessarily excluded from the scope of the invention, the scope of the invention being defined by the following claims.

1. A method for performing JTAG procedures, the method comprising:
incorporating the TMS signals in a TDI signal stream along with data signals.

2. The method as recited in claim 1, further comprising including the TMS signals in control packets.

3. The method as recited in claim 2, further comprising determining size of a data packet from bits in the control packets.

4. The method as recited in claim 3, wherein data determining the size of the data group is in preceding control packets.

5. The method as recited in claim 1, further comprising using the TMS control bits to control a path the JTAG state diagram.

6. The method as recited in claim 1, further comprising determining the position of a storage location by the non-TMS bits in the control packets.

7. A test configuration for performing JTAG procedures on an integrated circuit, the configuration comprising:
emulation unit, the emulation unit generating JTAG signals, the emulation unit formatting the JTAG signals wherein a TMS signal stream is eliminated, the TMS signals being incorporated in a TDI signal stream; and
an interface logic unit, the interface logic unit reformatting the TDI signal stream to provide TMS signals and data signals.

8. The test configuration as recited in claim 7, wherein the TDI signal stream is formatted to include control packets and data packets.

9. The test configuration as recited in claim 8, wherein the control packets include TMS signals.

10. The test configuration as recited in claim 8, wherein a group of control packets include bits identifying the number of data bits in a data packet following the group of control packets.

11. In a test configuration for applying JTAG test procedures to a an integrated circuit, an emulation unit generating the JTAG signals and an interface logic unit applying test signals to the integrated circuit, a formatting unit comprising:
a combining unit, the combining units combining a TMS signal stream with a TDI signal stream, the combining unit sending the TDI signal stream in control packets and in data packets to the interface unit.

12. The formatting unit as recited in claim 11, wherein the control packets include bits identifying the number of data bits in a following packet.

13. The formatting unit as recited in claim 12, wherein the interface logic unit determines the state of the JTAG apparatus in response to the TMS signals in the TDI signal stream.

14. The formatting unit as recited in claim 11, wherein the control packets include non-TMS signals that identify a storage location.

15. The formatting units a recited in claim 11, wherein the interface logic unit applies the data signals to the data register.

16. The formatting unit as recited in claim 11, wherein the interface logic unit applies the data signals to the instruction register.
